(19) United States
(12) Patent Application Publication
(10) Pub. No.: US 2024/0179474 A1
(43) Pub. Date: May 30, 2024

(54) PIEZOELECTRIC FILM AND PIEZOELECTRIC ELEMENT

(71) Applicant: FUJIFILM Corporation, Tokyo (JP)

(72) Inventors: Yusuke KAGAWA, Minamiashigara-shi (JP); Eiki OZAWA, Minamiashigara-shi (JP)

(73) Assignee: FUJIFILM Corporation, Tokyo (JP)

(21) Appl. No.: 18/432,479

(22) Filed: Feb. 5, 2024

Related U.S. Application Data
(63) Continuation of application No. PCT/JP2022/028212, filed on Jul. 20, 2022.

(30) Foreign Application Priority Data
Aug. 27, 2021 (JP) 2021-138734

(51) Int. Cl. H04R 17/00; H10N 30/092; H10N 30/85; H10N 30/88

(52) U.S. Cl. CPC H04R 17/005; H10N 30/092; H10N 30/852; H10N 30/883

(57) ABSTRACT

Provided is a piezoelectric film including electrode layers on both surfaces of a piezoelectric layer which contains piezoelectric particles in a matrix containing a polymer material, in which it is possible to prevent operational failure due to dielectric breakdown between the electrode layers at an end part. The piezoelectric film includes a piezoelectric layer which contains piezoelectric particles in a matrix containing a polymer material, electrode layers which are provided on both surfaces of the piezoelectric layer, and protective layers which are provided on the electrode layers, in which the piezoelectric film further includes an edge surface sealing layer consisting of a material containing a resin, the edge surface sealing layer covering an edge surface of the piezoelectric film, and an inter-electrode distance on the edge surface of the piezoelectric film is 30 μm or more, and is 103% or more and less than 120% with respect to a thickness of the piezoelectric layer.

### CROSS-REFERENCE TO RELATED APPLICATIONS

This application is a Continuation of PCT International Application No. PCT/JP2022/028212 filed on Jul. 20, 2022, which claims priority under 35 U.S.C. § 119(a) to Japanese Patent Application No. 2021-138734 filed on Aug. 27, 2021. The above applications are hereby expressly incorporated by reference, in their entirety, into the present application.

### BACKGROUND OF THE INVENTION

### 1. Field of the Invention

The present invention relates to a piezoelectric film used for an electroacoustic transducer or the like, and a piezoelectric element.

### 2. Description of the Related Art

With reduction in thickness and weight of displays such as liquid crystal displays and organic electro luminescence (EL) displays, speakers used in these thin displays are also required to be thinner and lighter. In addition, with the development of flexible displays including flexible substrates such as plastics, speakers used in the flexible displays are also required to be flexible.

Examples of a typical shape of the speaker in the related art include a funnel-like so-called cone shape and a spherical dome shape. However, in a case where such a speaker is intended to be incorporated in the above-described thin display, there is a concern that lightness and flexibility of the speaker are impaired because the speaker cannot be sufficiently made thin. In addition, in a case where the speaker is attached externally, it is troublesome to carry the speaker.

Therefore, as a speaker which is thin and can be integrated into a thin display or a flexible display without impairing lightness and flexibility, a sheet-like piezoelectric film having flexibility and a property of stretching and contracting in response to an applied voltage has been suggested.

For example, a piezoelectric film (electroacoustic conversion film) disclosed in JP2014-014063A has been suggested as a sheet-like piezoelectric film which has flexibility and can stably reproduce a high-quality sound.

The piezoelectric film disclosed in JP2014-014063A includes a polymer-based piezoelectric composite material obtained by dispersing piezoelectric particles in a viscoelastic matrix consisting of a polymer material having viscoelasticity at normal temperature, thin film electrodes formed on both surfaces of the polymer-based piezoelectric composite material, and a protective layer formed on a surface of the thin film electrode.

### SUMMARY OF THE INVENTION

In such a piezoelectric film, by applying a driving voltage to the electrode layer, the polymer-based piezoelectric composite material stretches and contracts due to the stretch and contraction of the piezoelectric particles and the piezoelectric film vibrates to absorb the stretch and contraction. The piezoelectric film vibrates the air through the vibration and converts an electrical signal into a sound. In order to vibrate the piezoelectric film, the piezoelectric layer has a thickness of, for example, preferably 300 μm or less, which is extremely thin. In addition, the piezoelectric film may be cut into a desired shape and used as a cut sheet.

As described above, the piezoelectric layer of the piezoelectric film is extremely thin, and a distance between the electrode layers is extremely short. Therefore, in a case where a high voltage is applied, at an edge surface (cut surface) of the piezoelectric film, dielectric breakdown of air occurs between the electrode layers on both surfaces of the piezoelectric layer, causing the piezoelectric film to not operate properly. In addition, since the dielectric breakdown is discharge phenomenon accompanied by heat generation, in a case where the dielectric breakdown occurs in a state in which the piezoelectric film is incorporated in a product, there is a concern that a serious failure may occur.

An object of the present invention is to solve such problems of the related art, and to provide a piezoelectric film including electrode layers on both surfaces of a piezoelectric layer which contains piezoelectric particles in a matrix containing a polymer material, in which it is possible to prevent operational failure due to dielectric breakdown between the electrode layers at an end part, and to provide a piezoelectric element.

In order to solve the problems, the present invention has the following configuration.
[1] A piezoelectric film comprising:
a piezoelectric layer which contains piezoelectric particles in a matrix containing a polymer material;
electrode layers which are provided on both surfaces of the piezoelectric layer; and
protective layers which are provided on the electrode layers,
in which the piezoelectric film further includes an edge surface sealing layer consisting of a material containing a resin, the edge surface sealing layer covering an edge surface of the piezoelectric film, and
an inter-electrode distance on the edge surface of the piezoelectric film is 30 μm or more, and is 103% or more and less than 120% with respect to a thickness of the piezoelectric layer.
[2] The piezoelectric film according to [1],
in which the material of the edge surface sealing layer contains a thermoplastic resin.
[3] The piezoelectric film according to [1] or [2],
in which the material of the edge surface sealing layer contains an ultraviolet curable resin.
[4] The piezoelectric film according to any one of [1] to [3],
in which a thickness of the edge surface sealing layer formed on a main surface of the protective layer is 50 μm or less.
[5] The piezoelectric film according to any one of [1] to [4],
in which a width of the edge surface sealing layer in a plane direction on a main surface of the piezoelectric film is 100 μm or more and 5,000 μm or less.
[6] The piezoelectric film according to any one of [1] to [5],
in which a thickness of the edge surface sealing layer in a plane direction from the edge surface of the piezoelectric film is 50 μm or less.
[7] A piezoelectric element obtained by laminating a plurality of layers of the piezoelectric films according to any one of [1] to [6].
[8] A piezoelectric element obtained by laminating a plurality of layers of the piezoelectric film according to any one of [1] to [6] by folding the piezoelectric film one or more times.

According to the present invention, it is possible to provide a piezoelectric film including electrode layers on both surfaces of a piezoelectric layer which contains piezoelectric particles in a matrix containing a polymer material, in which it is possible to prevent operational failure due to dielectric breakdown between the electrode layers at an end part, and to provide a piezoelectric element.

### BRIEF DESCRIPTION OF THE DRAWINGS

FIG. 1 is a cross-sectional view conceptually showing an example of a piezoelectric film according to the embodiment of the present invention.

FIG. 2 is an enlarged view showing an end part of the piezoelectric film shown in FIG. 1.

FIG. 3 is a view conceptually showing an example of a piezoelectric layer used in the piezoelectric film according to the embodiment of the present invention.

FIG. 4 is a conceptual view for describing an example of a manufacturing method of the piezoelectric film according to the embodiment of the present invention.

FIG. 5 is a conceptual view for describing an example of the manufacturing method of the piezoelectric film according to the embodiment of the present invention.

FIG. 6 is a conceptual view for describing an example of the manufacturing method of the piezoelectric film according to the embodiment of the present invention.

FIG. 7 is a conceptual view for describing an example of the manufacturing method of the piezoelectric film according to the embodiment of the present invention.

FIG. 8 is a conceptual view for describing an example of the manufacturing method of the piezoelectric film according to the embodiment of the present invention.

FIG. 9 is a conceptual view for describing an example of the manufacturing method of the piezoelectric film according to the embodiment of the present invention.

FIG. 10 is a conceptual view for describing an example of the manufacturing method of the piezoelectric film according to the embodiment of the present invention.

FIG. 11 is a conceptual view showing an example of a flat speaker using the piezoelectric film according to the embodiment of the present invention.

FIG. 12 is a conceptual view for describing a shape of a piezoelectric film outside the scope of the present invention.

### DESCRIPTION OF THE PREFERRED EMBODIMENTS

Hereinafter, the piezoelectric film and the piezoelectric element according to the embodiment of the present invention will be described in detail based on suitable embodiments shown in the accompanying drawings.

Although configuration requirements to be described below are described based on representative embodiments of the present invention, the present invention is not limited to the embodiments. In addition, the drawings shown below are conceptual views for describing the present invention, and the thickness of each layer, the size of the constituent members, the positional relationship of the constituent members, and the like are different from the actual values.

Any numerical range expressed using “to” in the present specification refers to a range including the numerical values before and after the “to” as a lower limit value and an upper limit value, respectively.

### Piezoelectric Film

The piezoelectric film according to the embodiment of the present invention is
a piezoelectric film including a piezoelectric layer which contains piezoelectric particles in a matrix containing a polymer material, electrode layers which are provided on both surfaces of the piezoelectric layer, and protective layers which are provided on the electrode layers,
in which the piezoelectric film further includes an edge surface sealing layer consisting of a material containing a resin, the edge surface sealing layer covering an edge surface of the piezoelectric film, and
an inter-electrode distance on the edge surface of the piezoelectric film is 30 μm or more, and is 103% or more and less than 120% with respect to a thickness of the piezoelectric layer.

The piezoelectric film according to the embodiment of the present invention is used, for example, as an electroacoustic conversion film. Specifically, the piezoelectric film according to the embodiment of the present invention is used as a vibration plate of an electroacoustic transducer such as a piezoelectric speaker, a microphone, and a voice sensor.

In the electroacoustic transducer, in a case where the piezoelectric film is stretched in a plane direction due to application of a voltage to the piezoelectric film, the piezoelectric film moves upward (in the radiation direction of the sound) in order to absorb the stretched part. On the contrary, in a case where the piezoelectric film is contracted in the plane direction due to application of a voltage to the piezoelectric film, the piezoelectric film moves downward in order to absorb the contracted part.

The electroacoustic transducer converts vibration (sound) and an electrical signal using vibration caused by repeated stretch and contraction of the piezoelectric film and is used to input an electrical signal to the piezoelectric film to reproduce a sound due to the vibration in response to the electrical signal, convert the vibration of the piezoelectric film to an electrical signal by receiving a sound wave, and apply tactile sensation or transport an object through the vibration.

Specific examples of applications of the piezoelectric film include various acoustic devices of speakers such as full-range speakers, tweeters, squawkers, and woofers, speakers for headphones, noise cancellers, microphones, and pickups (sensors for musical instruments) used for musical instruments such as guitars. In addition, since the piezoelectric film according to the embodiment of the present invention is a non-magnetic material, the piezoelectric film according to the embodiment of the present invention can be suitably used as a noise canceller for MRI among noise cancellers.

In addition, since the electroacoustic transducer using the piezoelectric film according to the embodiment of the present invention is thin, light, and bendable, the electroacoustic transducer can be suitably used as wearable products such as hats, mufflers, and clothes, thin displays such as televisions and digital signage, buildings having a function as an acoustic device, ceilings of automobiles, curtains, umbrellas, wallpaper, windows, beds, and the like.

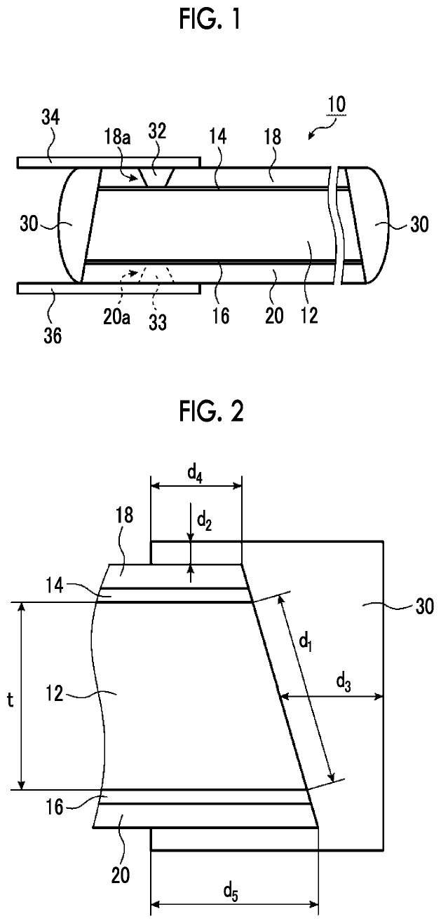

FIG. 1 conceptually shows an example of the piezoelectric film according to the embodiment of the present invention.

As shown in FIG. 1, a piezoelectric film 10 includes a piezoelectric layer 12, a first electrode layer 14 laminated on one surface of the piezoelectric layer 12, a first protective layer 18 laminated on the first electrode layer 14, a second electrode layer 16 laminated on the other surface of the piezoelectric layer 12, a second protective layer 20 laminated the second electrode layer 16, and an edge surface sealing layer 30.

The piezoelectric film 10 according to the embodiment of the present invention is, for example, a long piezoelectric film produced by roll-to-roll, or a cut sheet-like (sheet paper-like) film cut into a desired shape from a large-sized piezoelectric film. Therefore, an edge surface of the piezoelectric film 10 is a cut surface.

In addition, as a preferred aspect of the piezoelectric film 10, the first protective layer 18 has a through-hole 18a penetrating to the first electrode layer 14. The through-hole 18a is provided with a conductive first connecting member 32 connected to the first electrode layer 14. In addition, a first lead-out electrode 34 which is connected to the first connecting member 32 and connects the piezoelectric film 10 to an external power supply is provided.

The second protective layer 20 also has a through-hole 20a penetrating to the second electrode layer 16, and the through-hole 20a is provided with a conductive second connecting member 33. In addition, similarly, a second lead-out electrode 36 which is connected to the second connecting member 33 and connects the piezoelectric film 10 to an external power supply is also provided.

In the piezoelectric film 10 according to the embodiment of the present invention, various known piezoelectric layers can be used as the piezoelectric layer 12.

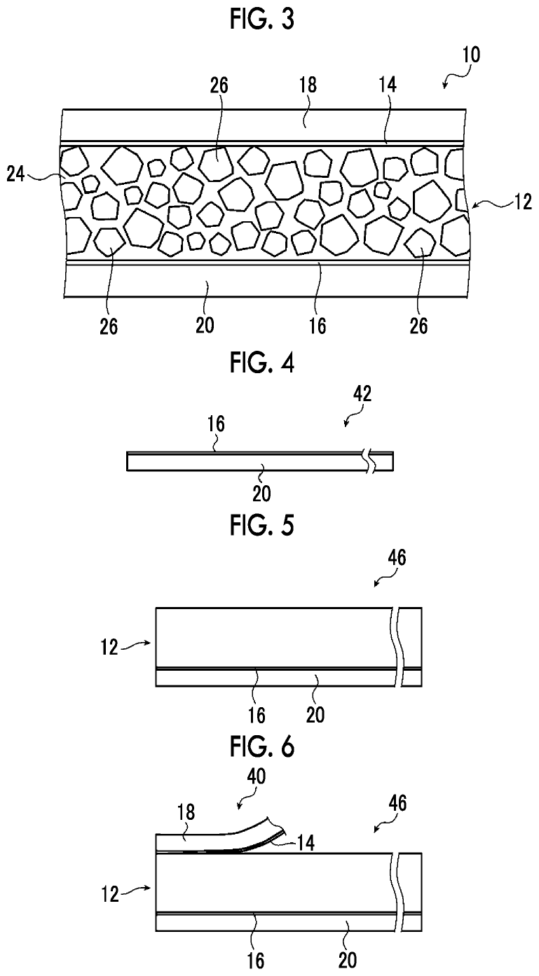

In the piezoelectric film 10 according to the embodiment of the present invention, as conceptually shown in FIG. 3, the piezoelectric layer 12 is preferably a polymer-based piezoelectric composite material containing piezoelectric particles 26 in a polymer matrix 24 containing a polymer material.

Here, it is preferable that the polymer-based piezoelectric composite material (piezoelectric layer 12) satisfies the following requirements. In the present invention, normal temperature is in a range of 0° C. to 50° C.

### (i) Flexibility

For example, in a case of being gripped in a state of being loosely bent with a sense of document such as a newspaper and a magazine as a portable device, the polymer-based piezoelectric composite material is continuously subjected to large bending deformation from the outside at a comparatively slow vibration of less than or equal to a few Hz. At this time, in a case where the polymer-based piezoelectric composite material is rigid, large bending stress is generated to that extent, and a crack is generated at an interface between the polymer matrix and the piezoelectric particles, which may lead to breakage. Accordingly, the polymer-based piezoelectric composite material is required to have suitable flexibility. In addition, in a case where strain energy is diffused into the outside as heat, the stress can be relaxed. Therefore, the polymer-based piezoelectric composite material is required to have a suitably large loss tangent.

### (ii) Acoustic Quality

In a speaker, the piezoelectric particles vibrate at a frequency of an audio band of 20 Hz to 20 kHz, and vibration energy causes the entire vibration plate (polymer-based piezoelectric composite material) to vibrate integrally so that sound is reproduced. Therefore, in order to increase transmission efficiency of the vibration energy, the polymer-based piezoelectric composite material is required to have appropriate rigidity. In addition, in a case where frequency characteristics of the speaker are smooth, an amount of a change in acoustic quality decreases in a case where the lowest resonance frequency f₀ is changed in association with a change in curvature of the speaker. Therefore, the polymer-based piezoelectric composite material is required to have a suitably large loss tangent.

It has been known that the lowest resonance frequency f₀ of the vibration plate for a speaker is represented by the following expression. Here, s represents the stiffness of the vibration system, and m represents the mass.

$$\\ Lowest resonance frequency : {f}_{0} = \frac{1}{2 π} \sqrt{\frac{s}{m}}$$

Here, as a degree of bending of the piezoelectric film, that is, a curvature radius of a bending portion increases, a mechanical stiffness s decreases, and thus the lowest resonance frequency f₀ decreases. That is, acoustic quality (volume and frequency characteristics) of the speaker changes depending on the curvature radius of the piezoelectric film.

Accordingly, the polymer-based piezoelectric composite material is required to exhibit a behavior of being rigid with respect to a vibration of 20 Hz to 20 kHz and being flexible with respect to a vibration of less than or equal to a few Hz. In addition, the loss tangent of the polymer-based piezoelectric composite material is required to be suitably large with respect to the vibration of all frequencies of 20 kHz or less.

In general, a polymer solid has a viscoelasticity relaxing mechanism, and a molecular movement with a large scale is observed as a decrease (relief) in a storage elastic modulus (Young's modulus) or a maximal value (absorption) in a loss elastic modulus along with an increase in temperature or a decrease in frequency. Among these, the relaxation due to a microbrown movement of a molecular chain in an amorphous region is referred to as main dispersion, and an extremely large relaxing phenomenon is observed. A temperature at which this main dispersion occurs is a glass transition point (Tg), and the viscoelasticity relaxing mechanism is most remarkably observed.

In the polymer-based piezoelectric composite material (piezoelectric layer 12), the polymer-based piezoelectric composite material exhibiting a behavior of being rigid with respect to the vibration of 20 Hz to 20 kHz and being flexible with respect to the slow vibration of less than or equal to a few Hz is achieved by using, as a matrix, a polymer material having a glass transition point at normal temperature, that is, a polymer material having viscoelasticity at normal temperature. In particular, from the viewpoint that such a behavior is suitably exhibited, it is preferable that the polymer material in which the glass transition point Tg at a frequency of 1 Hz is at normal temperature is used for the matrix of the polymer-based piezoelectric composite material.

In the polymer material serving as the matrix 24, it is preferable that the maximal value of a loss tangent Tanδ at a frequency of 1 Hz according to a dynamic viscoelasticity test at normal temperature is 0.5 or more.

In this manner, in a case where the polymer-based piezoelectric composite material is slowly bent due to an external force, stress concentration on the interface between the polymer matrix and the piezoelectric particles at the maximum bending moment portion is relaxed, and thus high flexibility can be expected.

In addition, in the polymer material serving as the matrix 24, it is preferable that a storage elastic modulus (E′) at a frequency of 1 Hz according to the dynamic viscoelasticity measurement is 100 MPa or more at 0° C. and 10 MPa or less at 50° C.

In this manner, a bending moment generated in a case where the polymer-based piezoelectric composite material is slowly bent due to the external force can be reduced, and at the same time, the polymer-based piezoelectric composite material can exhibit a behavior of being rigid with respect to an acoustic vibration of 20 Hz to 20 KHz.

In addition, it is more suitable that a relative permittivity of the polymer material serving as the matrix 24 is 10 or more at 25° C. Accordingly, in a case where a voltage is applied to the polymer-based piezoelectric composite material, a higher electric field is applied to the piezoelectric particles in the polymer matrix, and thus a large deformation amount can be expected.

However, in consideration of ensuring favorable moisture resistance and the like, it is suitable that the relative permittivity of the polymer material is 10 or less at 25° C.

Suitable examples of the polymer material satisfying such conditions include cyanoethylated polyvinyl alcohol (cyanoethylated PVA), polyvinyl acetate, poly(vinylidene chloride-co-acrylonitrile), a polystyrene-vinyl polyisoprene block copolymer, polyvinyl methyl ketone, and polybutyl methacrylate.

In addition, as these polymer materials, a commercially available product such as Hybrar 5127 (manufactured by Kuraray Co., Ltd.) can also be suitably used.

Among these, as the polymer material constituting the matrix 24, it is preferable to use a polymer material having a cyanoethyl group and particularly preferable to use cyanoethylated PVA. That is, in the piezoelectric film 10 according to the embodiment of the present invention, as the matrix 24 of the piezoelectric layer 12, it is preferable to use a polymer material containing a cyanoethyl group and particularly preferable to use cyanoethylated PVA.

In the following description, the above-described polymer materials typified by cyanoethylated PVA will also be collectively referred to as “polymer material having viscoelasticity at normal temperature”.

These polymer materials having viscoelasticity at normal temperature may be used alone or in combination (mixture) of two or more kinds thereof.

In the piezoelectric film 10 according to the embodiment of the present invention, a plurality of polymer materials may be used in combination as necessary for the matrix 24 of the piezoelectric layer 12.

That is, for the purpose of adjustment of dielectric characteristics, mechanical characteristics, or the like, other dielectric polymer materials may be added to the matrix 24 constituting the polymer-based piezoelectric composite material in addition to the polymer material having viscoelasticity at normal temperature, as necessary.

Examples of the dielectric polymer material which can be added thereto include fluorine-based polymers such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, and a polyvinylidene fluoride-tetrafluoroethylene copolymer; polymers having a cyano group or a cyanoethyl group, such as a vinylidene cyanide-vinyl acetate copolymer, cyanoethyl cellulose, cyanoethyl hydroxysaccharose, cyanoethyl hydroxycellulose, cyanoethyl hydroxypullulan, cyanoethyl methacrylate, cyanoethyl acrylate, cyanoethyl hydroxyethyl cellulose, cyanoethyl amylose, cyanoethyl hydroxypropyl cellulose, cyanoethyl dihydroxypropyl cellulose, cyanoethyl hydroxypropyl amylose, cyanoethyl polyacrylamide, cyanoethyl polyacrylate, cyanoethyl pullulan, cyanoethyl polyhydroxymethylene, cyanoethyl glycidol pullulan, cyanoethyl saccharose, and cyanoethyl sorbitol; and synthetic rubber such as nitrile rubber and chloroprene rubber.

Among these, a polymer material having a cyanoethyl group is suitably used.

In addition, in the matrix 24 of the piezoelectric layer 12, the number of these dielectric polymer materials is not limited to one, and a plurality of kinds of dielectric polymer materials may be added.

In addition, for the purpose of adjusting the glass transition point Tg of the matrix 24, a thermoplastic resin such as a vinyl chloride resin, polyethylene, polystyrene, a methacrylic resin, polybutene, and isobutylene, a thermosetting resin such as a phenol resin, a urea resin, a melamine resin, an alkyd resin, and mica, or the like may be added, in addition to the dielectric polymer material.

Furthermore, for the purpose of improving pressure sensitive adhesiveness, a viscosity imparting agent such as rosin ester, rosin, terpene, terpene phenol, and a petroleum resin may be added.

In the matrix 24 of the piezoelectric layer 12, the addition amount in a case of adding polymer materials other than the polymer material having viscoelasticity at normal temperature is not particularly limited, but is preferably set to 30% by mass or less in terms of the proportion of the polymer materials in the matrix 24.

In this manner, characteristics of the polymer material to be added can be exhibited without impairing the viscoelasticity relaxing mechanism in the matrix 24, so that preferred results such as an increase in permittivity, improvement of heat resistance, and improvement of adhesiveness between the piezoelectric particles 26 and the electrode layer can be obtained.

The polymer-based piezoelectric composite material serving as the piezoelectric layer 12 contains the piezoelectric particles 26 in the polymer matrix. The piezoelectric particles 26 are dispersed in the polymer matrix. It is preferable that the piezoelectric particles 26 are dispersed uniformly (substantially uniform) in the polymer matrix.

It is preferable that the piezoelectric particles 26 consist of ceramic particles having a perovskite type or wurtzite type crystal structure.

Examples of the ceramic particles constituting the piezoelectric particles 26 include particles such as lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFe₃).

A particle diameter of the piezoelectric particles 26 may be appropriately selected according to the size and the applications of the piezoelectric film 10. The particle diameter of the piezoelectric particles 26 is preferably 1 to 10 μm.

By setting the particle diameter of the piezoelectric particles 26 to be within the above-described range, preferred results in terms of achieving both excellent piezoelectric characteristics and flexibility can be obtained.

In the piezoelectric film 10, the ratio between the amount of the matrix 24 and the amount of the piezoelectric particles 26 in the piezoelectric layer 12 may be appropriately set according to the size and the thickness of the piezoelectric film 10 in the plane direction, the applications of the piezoelectric film 10, the characteristics required for the piezoelectric film 10, and the like.

A volume fraction of the piezoelectric particles 26 in the piezoelectric layer 12 is preferably 30% to 80% and more preferably 50% to 80%.

By setting the ratio between the amount of the matrix 24 and the amount of the piezoelectric particles 26 to be within the above-described range, preferred results in terms of achieving both of excellent piezoelectric characteristics and flexibility can be obtained.

In the piezoelectric film 10, a thickness of the piezoelectric layer 12 is not limited and may be appropriately set according to the size of the piezoelectric film 10, the applications of the piezoelectric film 10, the characteristics required for the piezoelectric film 10, and the like.

The thickness of the piezoelectric layer 12 is preferably 8 to 300 μm, more preferably 8 to 200 μm, still more preferably 10 to 150 μm, and particularly preferably 15 to 100 μm.

By setting the thickness of the piezoelectric layer 12 to be within the above-described ranges, preferred results in terms of achieving both ensuring of the rigidity and moderate elasticity can be obtained.

It is preferable that the piezoelectric layer 12 is subjected to a polarization treatment (poling) in the thickness direction. The polarization treatment will be described later in detail.

The laminated film of the piezoelectric film 10 shown in FIG. 1 has a configuration in which the second electrode layer 16 is provided on one surface of the piezoelectric layer 12, the second protective layer 20 is provided on a surface of the second electrode layer 16, the first electrode layer 14 is provided on the other surface of the piezoelectric layer 12, and the first protective layer 18 is provided on a surface of the first electrode layer 14. In the piezoelectric film 10, the first electrode layer 14 and the second electrode layer 16 form an electrode pair.

In other words, the laminated film constituting the piezoelectric film 10 according to the embodiment of the present invention has a configuration in which both surfaces of the piezoelectric layer 12 are sandwiched between the electrode pair, that is, the first electrode layer 14 and the second electrode layer 16, and further sandwiched between the first protective layer 18 and the second protective layer 20.

In this manner, a region sandwiched between the first electrode layer 14 and the second electrode layer 16 is driven according to the applied voltage.

In the present invention, the terms “first” and “second” in the first electrode layer 14 and the second electrode layer 16, and the like are used to explain the piezoelectric film 10 according to the embodiment of the present invention for convenience.

Therefore, the terms “first” and “second” in the piezoelectric film 10 according to the embodiment of the present invention have no technical meanings and are irrelevant to the actual usage state.

The piezoelectric film 10 according to the embodiment of the present invention may include, in addition to those layers, for example, a bonding layer for bonding the electrode layer and the piezoelectric layer 12 to each other, and a bonding layer for bonding the electrode layer and the protective layer to each other.

The bonding agent may be an adhesive or a pressure sensitive adhesive. In addition, the same material as the polymer material obtained by removing the piezoelectric particles 26 from the piezoelectric layer 12, that is, the matrix 24 can also be suitably used as the bonding agent. The bonding layer may be provided on both the first electrode layer 14 side and the second electrode layer 16 side, or may be provided only on one of the first electrode layer 14 side or the second electrode layer 16 side.

The first protective layer 18 and the second protective layer 20 in the piezoelectric film 10 have a function of coating the first electrode layer 14 and the second electrode layer 16 and imparting moderate rigidity and mechanical strength to the piezoelectric layer 12. That is, the piezoelectric layer 12 including the matrix 24 and the piezoelectric particles 26 in the piezoelectric film 10 according to the embodiment of the present invention exhibits extremely excellent flexibility under bending deformation at a slow vibration, but may have insufficient rigidity or mechanical strength depending on the applications. As a compensation for this, the piezoelectric film 10 is provided with the first protective layer 18 and the second protective layer 20.

The first protective layer 18 and the second protective layer 20 have the same configuration despite of different disposition positions. Accordingly, in the following description, in a case where it is not necessary to distinguish the first protective layer 18 from the second protective layer 20, both members are collectively referred to as a protective layer.

The protective layer is not limited, and various sheet-like materials can be used as the protective layer, and suitable examples thereof include various resin films. Among these, from the viewpoint of excellent mechanical characteristics and heat resistance, a resin film consisting of polyethylene terephthalate (PET), polypropylene (PP), polystyrene (PS), polycarbonate (PC), polyphenylene sulfite (PPS), polymethylmethacrylate (PMMA), polyetherimide (PEI), polyimide (PI), polyamide (PA), polyethylene naphthalate (PEN), triacetyl cellulose (TAC), a cyclic olefin-based resin, and the like is suitably used.

A thickness of the protective layer is not limited. In addition, the thicknesses of the first protective layer 18 and the second protective layer 20 are basically the same as each other, but may be different from each other.

Here, in a case where the rigidity of the protective layer is extremely high, not only is the stretch and contraction of the piezoelectric layer 12 constrained, but also the flexibility is impaired. Therefore, it is advantageous that the thickness of the protective layer decrease except for a case where the mechanical strength or excellent handleability as a sheet-like material is required.

In a case where the thickness of the first protective layer 18 and the thickness of the second protective layer 20 are each twice or less the thickness of the piezoelectric layer 12, preferred results from the viewpoints of achieving both ensuring of the rigidity and moderate elasticity, and the like can be obtained.

For example, in a case where the thickness of the piezoelectric layer 12 is 50 μm and the first protective layer 18 and the second protective layer 20 consist of PET, each of the thicknesses of the first protective layer 18 and the second protective layer 20 is preferably 100 μm or less, more preferably 50 μm or less, and still more preferably 25 μm or less.

In the piezoelectric film 10 (laminated film), the first electrode layer 14 is formed between the piezoelectric layer 12 and the first protective layer 18, and the second electrode layer 16 is formed between the piezoelectric layer 12 and the second protective layer 20. The first electrode layer 14 and the second electrode layer 16 are provided to apply an electric field to the piezoelectric film 10 (piezoelectric layer 12).

The first electrode layer 14 and the second electrode layer 16 are basically the same, except that the positions are different. Accordingly, in the following description, in a case where it is not necessary to distinguish the first electrode layer 14 and the second electrode layer 16, both members are collectively referred to as an electrode layer.

In the piezoelectric film according to the embodiment of the present invention, a forming material of the electrode layer is not limited, and various conductors can be used as the forming material. Specific examples thereof include conductive polymers such as carbon, palladium, iron, tin, aluminum, nickel, platinum, gold, silver, copper, chromium, molybdenum, alloys thereof, indium tin oxide, and polyethylene dioxythiophene-polystyrene sulfonic acid (PEDOT/PPS).

Among these, copper, aluminum, gold, silver, platinum, or indium tin oxide is suitably exemplified. Among these, from the viewpoint of the conductivity, the cost, and the flexibility, copper is more preferable.

In addition, a method of forming the electrode layer is not limited, and various known methods, for example, a vapor-phase deposition method (a vacuum film forming method) such as vacuum vapor deposition or sputtering, a film forming method using plating, a method of bonding a foil formed of the materials described above, and a coating method can be used.

Among these, particularly from the viewpoint of ensuring the flexibility of the piezoelectric film 10, a thin film made of copper or aluminum formed by vacuum vapor deposition is suitably used as the electrode layer. Among these, a thin film made of copper, which is formed by vacuum vapor deposition, is particularly suitably used.

Thicknesses of the first electrode layer 14 and the second electrode layer 16 are not limited. In addition, the thicknesses of the first electrode layer 14 and the second electrode layer 16 are basically the same as each other, but may be different from each other.

Here, similarly to the protective layer described above, in a case where the rigidity of the electrode layer is extremely high, not only is the stretch and contraction of the piezoelectric layer 12 constrained, but also the flexibility is impaired. Therefore, it is advantageous that the thickness of the electrode layer is reduced in a case where an electric resistance is not excessively high.

In the piezoelectric film 10 according to the embodiment of the present invention, it is suitable that a product of the thickness of the electrode layer and the Young's modulus thereof is less than a product of the thickness of the protective layer and the Young's modulus thereof because the flexibility is not considerably impaired.

For example, in a case of a combination consisting of the protective layer formed of PET (Young's modulus: approximately 6.2 GPa) and the electrode layer consisting of copper (Young's modulus: approximately 130 GPa), assuming that the thickness of the protective layer is 25 μm, the thickness of the electrode layer is preferably 1.2 μm or less, more preferably 0.3 μm or less, and still more preferably 0.1 μm or less.

The piezoelectric film 10 has a configuration in which the piezoelectric layer 12 is sandwiched between the first electrode layer 14 and the second electrode layer 16, and further sandwiched between the first protective layer 18 and the second protective layer 20.

It is preferable that, in such a piezoelectric film 10, the maximal value at which the loss tangent (Tanδ) at a frequency of 1 Hz according to dynamic viscoelasticity measurement is 0.1 or more is present at normal temperature.

In this manner, even in a case where the piezoelectric film 10 is subjected to large bending deformation at a relatively slow vibration of less than or equal to a few Hz from the outside, since the strain energy can be effectively diffused to the outside as heat, occurrence of cracks at the interface between the polymer matrix and the piezoelectric particles can be prevented.

In the piezoelectric film 10, it is preferable that the storage elastic modulus (E′) at a frequency of 1 Hz according to the dynamic viscoelasticity measurement is 10 to 30 GPa at 0° C. and 1 to 10 GPa at 50° C.

In such a manner, the piezoelectric film 10 may have large frequency dispersion in the storage elastic modulus (E′) at normal temperature. That is, the piezoelectric film 10 can exhibit a behavior of being rigid with respect to the vibration of 20 Hz to 20 kHz and being flexible with respect to the vibration of less than or equal to a few Hz.

In the piezoelectric film 10, it is preferable that a product of the thickness and the storage elastic modulus (E′) at a frequency of 1 Hz according to the dynamic viscoelasticity measurement is 1.0×10⁶ to 2.0×10⁶ N/m at 0° C. and 1.0×10⁵ to 1.0×10⁶ N/m at 50° C.

In this manner, the piezoelectric film 10 may have moderate rigidity and mechanical strength within a range not impairing the flexibility and the acoustic characteristics.

Furthermore, in the piezoelectric film 10, it is preferable that the loss tangent (Tanδ) at a frequency of 1 kHz at 25° C. is 0.05 or more in a master curve obtained from the dynamic viscoclasticity measurement.

In this manner, the frequency characteristics of the speaker including the piezoelectric film 10 are smooth, so that an amount of change in acoustic quality in a case where the lowest resonance frequency f₀ is changed according to a change in curvature of the speaker (piezoelectric film 10) can be decreased.

As shown in FIG. 1, in the piezoelectric film 10, the first protective layer 18 has a through-hole 18a penetrating to the first electrode layer 14. The through-hole 18a is provided with a conductive first connecting member 32 connected to the first electrode layer 14. In addition, a first lead-out electrode 34 which is connected to the first connecting member 32 and connects the piezoelectric film 10 to an external power supply is provided.

Similarly, the second protective layer 20 also has the identical through-hole 20a, and the through-hole 20a is provided with a conductive second connecting member 33 connected to the second electrode layer 16. In addition, similarly, a second lead-out electrode 36 which is connected to the second connecting member 33 and connects the piezoelectric film 10 to an external power supply is also provided.

It is preferable that the first lead-out electrode 34 and the second lead-out electrode 36 are provided at different positions in the plane direction of the piezoelectric film 10 (laminated film). In FIG. 1, the first lead-out electrode 34 and the second lead-out electrode 36 are provided at different positions in a direction orthogonal to the paper surface of the figure.

In the illustrated example, the first lead-out electrode 34 and the second lead-out electrode 36 are led out in an identical direction, but the present invention is not limited thereto and various configurations can be used.

For example, the first lead-out electrode 34 and the second lead-out electrode 36 may be led out in opposite directions, or the first lead-out electrode 34 and the second lead-out electrode 36 may be led out so as to be orthogonal to each other.

Since a method of leading out the electrode in the first electrode layer 14 and a method of leading out the electrode in the second electrode layer 16 are the same as each other, the following description will be made using the first electrode layer 14 as an example.

The through-hole 18a (through-hole 20a) is a through-hole drilled in the first protective layer 18 (second protective layer 20) in order to form the first connecting member 32 (second connecting member 33) which connects the first electrode layer 14 and the first lead-out electrode 34 (the second electrode layer and the second lead-out electrode 36).

A size of the through-hole 18a is not limited, and depending on the forming material of the first electrode layer 14 and the first lead-out electrode 34, the size of the first lead-out electrode 34, the size of the piezoelectric film 10, and the like, the size of the through-hole 18a may be appropriately set to a size that allows formation of the first connecting member 32 which provides sufficient conduction.

A shape of the through-hole 18a is not limited. Therefore, various shapes such as a truncated cone shape, a cylindrical shape, and a square tubular shape can be used as the shape of the through-hole.

As a method of forming the through-hole 18a, various known methods can be used depending on the forming material of the first protective layer 18.

Examples thereof include a method of removing the first protective layer 18 by burning (ablation) the layer with a laser beam such as a laser beam having a wavelength of 10.6 μm by a carbon dioxide laser to form the through-hole 18a. For example, the through-hole 18a may be formed at a desired position of the first protective layer 18 by scanning the formation position of the through-hole 18a in the first protective layer 18 with a laser beam. In this case, a through-hole 18a having a desired thickness can be formed by adjusting the intensity, scanning speed (that is, treatment time with the laser beam), and the like of the laser beam.

In addition, a method of forming the through-hole 18a by dissolving the first protective layer 18 with an organic solvent can also be used. For example, in a case where the first protective layer 18 is formed of PET, the through-hole 18a can be formed by using hexafluoroisopropanol or the like. In a case where a solvent is used, the through-hole 18a may be formed at a desired position by using a mask or the like in the same manner as etching in photolithography or the like. In this case, the through-hole 18a having a desired thickness can be formed by adjusting the treatment time and the concentration of the organic solvent.

The through-hole 18a is provided with the first connecting member 32 (second connecting member 33). The first connecting member 32 electrically connects the first electrode layer 14 and the first lead-out electrode 34.

In the piezoelectric film 10 according to the embodiment of the present invention, various types of members consisting of a conductive material which can be inserted into the through-hole 18a can be used as the first connecting member 32.

Specific examples thereof include a metal paste obtained by dispersing metal particles such as silver, copper, and gold in a binder made of a thermosetting resin such as epoxy resin and polyimide; a metal paste obtained by dispersing the same metal particles in a binder made of a resin which is cured at approximately room temperature, such as an acrylic resin; a metal paste that is heat-cured as a single metal by complex metal; a metal tape such as copper foil tape; and a metal member which can be inserted into the through-hole 18a.

The first lead-out electrode 34 (second lead-out electrode 36) is a wiring line which is electrically connected to the first connecting member 32 and is used for electrically connecting an external power supply and the piezoelectric film 10 to each other. Therefore, the first lead-out electrode 34 extends to the outside of the laminated film obtained by laminating the piezoelectric layer 12, the electrode layers, and the protective layers, in the plane direction.

The first lead-out electrode 34 is not limited, and various known ones used as a wiring line which electrically connects an electrode or the like to a power supply and an external device, such as a metal foil, for example, a copper foil, and various metal wires, can be used.

In addition, a length of the first lead-out electrode 34 outside the laminated film in the plane direction may be appropriately set according to the application of the piezoelectric film 10, the device to which the piezoelectric film 10 is connected, the installation position of the piezoelectric film 10, and the like.

The first lead-out electrode 34 and the first connecting member 32 may be bonded to each other as necessary. The first lead-out electrode 34 and the first connecting member 32 may be bonded to each other by a known method.

Examples thereof include a method of using a conductive bonding agent (such as an adhesive and a pressure sensitive adhesive) and a method of using conductive double-sided tape. In addition, a method in which, by using a metal paste such as a silver paste for the first connecting member 32 and using a copper foil, a conductive wire, or the like for the first lead-out electrode 34, the first connecting member 32 and the first lead-out electrode 34 have adhesiveness and are bonded to each other can be used.

In the piezoelectric film 10 shown in FIG. 1, as a preferred aspect in which the edge surface sealing layer 30 described later is easily formed on the entire edge surface of the laminated film, by forming a through-hole in the protective layer, providing an electrode connecting member in the through-hole, and connecting the electrode connecting member to a lead-out electrode, the electrode is led out for connection to an external power supply.

However, the piezoelectric film according to the embodiment of the present invention is not limited thereto, and various configurations can be used for leading the electrode out.

For example, a wiring line for leading out, such as a rod-like or sheet-like (film-like or plate-like) wiring line, is provided between the protective layer and the piezoelectric layer or between the electrode layer and the protective layer, and this wiring line for leading out may be connected to the lead-out electrode. Alternatively, the wiring line for leading out may be used as it is as the lead-out electrode. Alternatively, a part of the protective layer and the electrode layer may be projected from the piezoelectric layer in the plane direction, and a lead-out electrode may be connected to the projected electrode layer as the wiring line for leading out.

Here, the piezoelectric film according to the embodiment of the present invention further includes an edge surface sealing layer consisting of a material containing a resin, and has a configuration in which the edge surface scaling layer covering an edge surface of the piezoelectric film, and an inter-electrode distance on the edge surface of the piezoelectric film is 30 82 m or more, and is 103% or more and less than 120% with respect to the thickness of the piezoelectric layer.

Since the piezoelectric film according to the embodiment of the present invention has such a configuration, it is possible to suitably prevent dielectric breakdown (short circuit) between the first electrode layer and the second electrode layer at the end part.

This point will be described with reference to FIG. 2. FIG. 2 is an enlarged view showing an end part of the piezoelectric film 10 shown in FIG. 1.

As shown in FIG. 2, the piezoelectric film 10 includes the edge surface sealing layer 30 consisting of a material containing a resin, which is formed to cover at least an edge surface of the piezoelectric film 10, that is, an edge surface of a laminated film including the first protective layer 18, the first electrode layer 14, the piezoelectric layer 12, the second electrode layer 16, and the second protective layer 20. In the example shown in FIG. 2, the edge surface scaling layer 30 covers the entire region of the edge surface of the laminated film in the thickness direction by being formed from a main surface of the first protective layer 18 to a main surface of the second protective layer 20. The main surface is the maximum surface of a sheet-like material (a layer, a film, or a plate-like material).

In addition, the edge surface of the piezoelectric film 10 (edge surface of the laminated film) is not perpendicular to the main surface of the laminated film (main surface of the first protective layer 18 and the second protective layer 20), and is inclined. Since the edge surface is inclined, an inter-electrode distance di between the first electrode layer 14 and the second electrode layer 16 on the edge surface is more than 100% with respect to a thickness t of the piezoelectric layer. In a case where a ratio of the inter-electrode distance di between the first electrode layer 14 and the second electrode layer 16 in the edge surface of the laminated film to the thickness t of the piezoelectric layer is defined as “ratio p”, in the present invention, the ratio p is 103% or more and less than 120% and the inter-electrode distance di is 30 μm or more.

As described above, since the piezoelectric film (piezoelectric layer) is extremely thin, the inter-electrode distance between the first electrode layer and the second electrode layer is extremely close. Therefore, in a case where a high voltage is applied, at the edge surface of the piezoelectric film, dielectric breakdown of air occurs between the electrode layers on both surfaces of the piezoelectric layer, causing the piezoelectric film to not operate properly. In addition, since the dielectric breakdown is discharge phenomenon accompanied by heat generation, in a case where the dielectric breakdown occurs in a state in which the piezoclectric film is incorporated in a product, there is a concern that a serious failure may occur.

On the contrary, in the piezoelectric film according to the embodiment of the present invention, since the ratio p is 103% or more and less than 120% and the inter-electrode distance d₁ is 30 μm or more, the inter-electrode distance with a length equal to or more than the thickness of the piezoelectric layer 12 is ensured, and the edge surface of the piezoelectric film is covered with the edge surface sealing layer 30 to ensure insulating properties. Therefore, it is possible to suppress the occurrence of dielectric breakdown between the electrode layers on both surfaces of the piezoelectric layer 12 on the edge surface of the piezoelectric film 10. In this manner, it is possible to suppress appropriate operation of the piezoelectric film due to the dielectric breakdown between the electrode layers, and it is possible to suppress failure of a product into which the piezoelectric film is incorporated due to heat generation associated with the dielectric breakdown.

Here, as the ratio p is larger, a longer inter-electrode distance d₁ can be ensured relative to the thickness of the piezoelectric layer 12. However, as shown in FIG. 12, in a case where the ratio p is too large, the edge surface has a sharp shape, and it is difficult to cover the entire edge surface with the edge surface sealing layer 30. Since a part of the edge surface is not covered with the edge surface sealing layer 30, the dielectric breakdown between the electrode layers is likely to occur. From this point, the ratio p is set to be less than 120%.

From the viewpoint of more suitably suppressing the dielectric breakdown between the electrode layers, the ratio p is preferably 105% to 115% and more preferably 110% to 115%.

From the viewpoint of more suitably suppressing the dielectric breakdown between the electrode layers, the inter-electrode distance di is preferably 30 μm or more, more preferably 40 μm or more, and still more preferably 50 μm or more.

In the end part of the piezoelectric film 10 in the present invention, the inter-electrode distance d₁ between the first electrode layer 14 and the second electrode layer 16 on the edge surface and the ratio p of the inter-electrode distance di to the thickness t of the piezoelectric layer 12 can be measured by various known methods.

Examples thereof include a measuring method in which, using a scanning electron microscope (SEM) equipped with an energy dispersive X-ray spectrometry (EDS or EDX), the edge surface of the piezoelectric film 10, that is, an end part of a cut surface is observed, and an elemental mapping of a material forming the electrode layer is carried out. Commercially available products may be used for the SEM and the EDX. Examples of the commercially available products include SU8220 (manufactured by Hitachi High-Tech Corporation) as the SEM and XFash 5060FQ (manufactured by Bruker Corporation) as the EDS.

In this case, in order to measure the inter-electrode distance d₁, the piezoelectric film is embedded from the end portion to a depth of 5 mm or more from the end part such that the measurement position of the inter-electrode distance d₁ is included, the piezoelectric film is cut using a microtome, and polishing is carried out as necessary for measuring the inter-electrode distance d₁ between the first electrode layer 14 and the second electrode layer 16.

That is, first, the piezoelectric film is embedded from the end portion to a depth of 5 mm or more from the end part such that the measurement position of the inter-electrode distance d₁ is included, the piezoelectric film is cut using a microtome, and then the end part of the piezoelectric film 10 is observed using the SEM equipped with the EDS (SEM-EDS) on this cut surface to perform elemental analysis of the end part of the observation region using the EDS.

Next, based on the results of the elemental analysis, the forming material of the first electrode layer 14 and the second electrode layer 16 is subjected to elemental mapping to obtain an image of the mapping result. For example, in a case where the forming material of the first electrode layer 14 and the second electrode layer 16 is copper, copper mapping is performed based on the results of the elemental analysis to obtain an image of the copper mapping result.

After the image of the elemental mapping performed on the forming material of the electrode layers is obtained, the inter-electrode distance d₁ between the first electrode layer 14 and the second electrode layer 16 on the edge surface is measured in the end part of the piezoelectric film 10.

Meanwhile, in a case where the thickness t of the piezoelectric layer 12 is known from the catalog value or the like of the piezoelectric film 10, the numerical value thereof may be used.

Alternatively, the thickness t of the piezoelectric layer 12 may be measured by a known method at the time of formation of the piezoelectric layer 12 in the process of manufacturing the piezoelectric film 10, which will be described later. Alternatively, the thickness t of the piezoelectric layer 12 may be calculated from a coating thickness and composition of a coating material forms the piezoelectric layer 12 in the process of manufacturing the piezoelectric film 10, which will be described later. Alternatively, the thickness t of the piezoelectric layer 12 may be obtained by measuring the total thickness at the time of formation the piezoelectric layer 12, partially removing the piezoelectric layer 12, measuring a thickness thereof, and calculating a difference therebetween.

In a case where the thickness t of the piezoelectric layer 12 cannot be measured (known) by these methods, the thickness t of the piezoelectric layer 12 may be measured by the following method.

The piezoelectric film 10 is embedded in a resin. It is preferable that the piezoelectric film 10 is embedded in the resin from a cut surface thereof to a depth of 5 mm or more. The resin used for embedding may be appropriately set according to the forming material, the size (the area of the maximum surface and the thickness), and the like of the piezoelectric film 10. The resin used for embedding may be used in a mixture of a plurality of kinds thereof as necessary.

After the piezoelectric film 10 is embedded in the resin, the piezoelectric film 10 embedded in the resin is cut in a straight line at an optional place. The piezoelectric film 10 may be cut by a known method such as a method of using a microtome or the like.

It is preferable that the cutting is performed at a position where the center of the cut surface in the longitudinal direction is positioned inside from all the end parts (edge surfaces) of the piezoelectric film 10 to a depth of 5 mm or more.

Next, the cut surface is polished as necessary. The polishing may be performed by a known method.

Furthermore, elemental mapping of the forming material of the first electrode layer 14 and the second electrode layer 16 by the SEM-EDS described above is performed at the central portion of the cut surface in the longitudinal direction. Next, from the image of the elemental mapping, a distance between an inner surface of the first electrode layer 14 and an inner surface of the second electrode layer 16 in the thickness direction is measured at the center of the cut surface in the longitudinal direction, and this distance is defined as the thickness t of the piezoelectric film at the cut surface.

The thickness of the piezoelectric layer 12 on the cut surface is measured on any 5 cross sections, and an average value thereof is defined as the thickness t of the piezoelectric layer 12 in the piezoelectric film 10 to be measured.

From the measurement results of the thickness t and the inter-electrode distance d₁, the ratio p [%] of the inter-electrode distance di between the first electrode layer 14 and the second electrode layer 16 in the end part of the piezoelectric film 10 to the thickness t of the piezoelectric layer 12 is calculated by the following expression.

p[%]=(d/t)×100

Here, for example, in a case where the cut sheet-like piezoelectric film 10 is rectangular, the piezoelectric film has four edge surfaces (cut surfaces). Accordingly, for one corner part, the ratio p of one end part of a side A observed by the SEM from the direction of an arrow a orthogonal to the side A and the ratio p of one edge surface of a side B observed by the SEM from the direction of an arrow b orthogonal to the side B can be measured.

That is, in a case where the piezoelectric film 10 is rectangular, the ratio p of the end parts of the piezoelectric film 10 at 8 sites in total can be measured for corner parts at 4 sites.

The piezoelectric film according to the embodiment of the present invention is not limited to the rectangle as described above, and various shapes can be used. Examples of a planar shape, that is, a shape of the main surface of the piezoelectric film according to the embodiment of the present invention include a circular shape, an elliptical shape, a triangular shape, and pentagonal or more polygonal shapes.

In any shapes, the ratio p [%] of the inter-electrode distance d₁ to the thickness t may be measured in accordance with the above-described method in which the end part is observed with the SEM-EDS and elemental mapping of the forming material of the electrode is performed.

In the present invention, in a case where the piezoelectric film has a polygonal shape, the ratio p for the piezoelectric film 10 is obtained by measuring the ratio p from two directions with all corner parts as measurement targets, and calculating an average value of all the ratios p (number of corner parts×2 sites). The polygonal shape also includes a shape in which the corner parts are curved with a chamfer or the like. In addition, in a case where the piezoelectric film has a shape other than the polygonal shape, such as a circular shape and an elliptical shape, the ratio p is measured at 8 sites obtained by equally dividing the outer periphery, and the average value thereof is defined as the ratio p for the piezoelectric film 10.

As described above, the edge surface sealing layer 30 consists of a material containing a resin, and suppresses the dielectric breakdown between the electrode layers.

The forming material of the edge surface sealing layer 30 is not limited, and various known materials can be used as long as the materials have insulating properties. Examples thereof include polyimide and polyethylene terephthalate having heat resistance.

As the resin contained in the material of the edge surface sealing layer 30, a thermoplastic resin or an ultraviolet (UV) curable resin is preferable.

Examples of the thermoplastic resin include polyolefin, polypropylene, polyamide, an ethylene/vinyl acetate copolymer resin (EVA), and a synthetic rubber.

Examples of the UV curable resin include urethane acrylate and epoxy.

Since the edge surface sealing layer 30 needs to be formed on the edge surface of the piezoelectric film 10 which is extremely thin, for example, in a case of forming the edge surface sealing layer 30 by applying a solution in which a resin material is dissolved in a solvent, the solution being to be the edge surface sealing layer 30, onto the edge surface of the piezoelectric film 10, it takes time for drying and curing. Therefore, the solution may be pulled by surface tension or the like to expose a part of the edge surface, such that it is not possible to form the edge surface sealing layer 30 covering the entire edge surface.

On the other hand, in a case where the thermoplastic resin which is cured by cooling and the UV curable resin which is cured by irradiation with UV light are used as the edge surface sealing layer 30, the curing time can be shortened, and it is possible to prevent a part of the edge surface from being exposed due to the solution being pulled by the surface tension or the like. Accordingly, it is possible to easily form the edge surface sealing layer 30 covering the entire edge surface.

A thickness, shape, and the like of the edge surface sealing layer 30 are not particularly limited as long as the dielectric breakdown between the electrode layers can be suppressed. For example, in the example shown in FIG. 2, the edge surface sealing layer 30 is formed to cover a part of the main surface of the first protective layer 18, the entire region of the edge surface in the thickness direction, and a part of the main surface of the second protective layer 20, but the present invention is not limited thereto, and it is preferable to cover at least the entire edge surface of the piezoelectric film 10.

From the viewpoint of more suitably suppressing the dielectric breakdown between the electrode layers, a thickness d₃ of the edge surface sealing layer 30 from the edge surface of the piezoelectric film 10 in the plane direction (see FIG. 2) is preferably 5 μm to 20 μm and more preferably 10 μm to 15 μm. From the viewpoint of productivity, there is a limit to the thickness d₃ of the edge surface sealing layer 30 in the plane direction. From this point, the upper limit of the thickness d₃ is preferably within the above-described range.

The thickness d₃ is defined as follows.

With a measurement range from one main surface of the piezoelectric film to the other main surface (=thickness range of the piezoelectric film), a thickness in a horizontal direction from the edge surface of the piezoelectric film to the end part of the edge surface scaling layer is measured in an area divided into 5 equal parts. The average of the obtained 5 measurement data is defined as the thickness d₃ on the cut surface. The same applies to five cross sections, and an average thereof is defined as the final d₃.

As shown in the example of FIG. 2, in the case where the edge surface sealing layer 30 is also formed in a part of the first protective layer 18 on the main surface and a part of the second protective layer 20 on the main surface, in a case where a thickness d₂ of the edge surface sealing layer 30 (see FIG. 2) is too large, the vibration of the piezoelectric film 10 may be inhibited. From this viewpoint, the thickness d₂ of the edge surface sealing layer 30 formed on the main surface of the protective layer is preferably 50 μm or less, more preferably 10 μm to 40 μm, and still more preferably 10 μm to 20 μm.

In addition, from the viewpoint of suppressing the inhibition of the vibration of the piezoelectric film 10, an average value of a width d₄ of the edge surface sealing layer 30 formed on the main surface of the first protective layer 18 in the plane direction and a width d₅ of the edge surface sealing layer 30 formed on the main surface of the second protective layer 20 in the plane direction is preferably 3,000 μm or less, more preferably 100 μm to 2,000 μm, and still more preferably 500 μm to 1,500 μm.

In the example shown in FIG. 2, a cross-sectional shape of the edge surface of the edge surface sealing layer 30 is a substantially linear shape, but the present invention is not limited thereto, and the cross-sectional shape thereof may be a substantially circular shape, an elliptical shape, or the like.

In addition, it is sufficient that the edge surface sealing layer 30 covers at least a part of the edge surface of the piezoelectric film 10 in a circumferential direction, and it is preferable to cover the entire region in the circumferential direction. That is, it is preferable that the edge surface sealing layer 30 covers the entire edge surface of the piezoelectric film 10.

Next, an example of the manufacturing method of the piezoelectric film 10 according to the embodiment of the present invention will be described with reference to the conceptual views of FIGS. 4 to 10.

First, as shown in FIG. 4, a sheet-like material 42 in which the second electrode layer 16 has been formed on a surface of the second protective layer 20 is prepared. Furthermore, as conceptually shown in FIG. 6, a sheet-like material 40 in which the first electrode layer 14 has been formed on a surface of the first protective layer 18 is prepared.

The sheet-like material 42 may be produced by forming a copper thin film or the like as the second electrode layer 16 on the surface of the second protective layer 20 using vacuum vapor deposition, sputtering, plating, or the like. Similarly, the sheet-like material 40 may be produced by forming a copper thin film or the like as the first electrode layer 14 on the surface of the first protective layer 18 using vacuum vapor deposition, sputtering, plating, or the like.

Alternatively, a commercially available sheet-like material in which a copper thin film or the like is formed on a protective layer may be used as the sheet-like material 42 and/or the sheet-like material 40.

The sheet-like material 42 and the sheet-like material 40 may be exactly the same or different from each other.

In a case where the protective layer is extremely thin and thus the handleability is degraded, the protective layer with a separator (temporary support) may be used as necessary. PET having a thickness of 25 to 100 μm, or the like can be used as the separator. The separator may be removed after thermal compression bonding of the electrode layer and the protective layer.

Next, as shown in FIG. 5, the second electrode layer 16 of the sheet-like material 42 is coated with a coating material (coating composition) forming the piezoelectric layer 12, and the coating material is cured to form the piezoelectric layer 12. In this manner, a piezoelectric laminate 46 in which the sheet-like material 42 and the piezoelectric layer 12 are laminated is produced.

The piezoelectric layer 12 can be formed by various methods depending on the forming material of the piezoelectric layer 12.

As an example, first, the coating material is prepared by dissolving the above-described polymer material such as cyanoethylated PVA in an organic solvent, adding the piezoelectric particles 26 such as PZT particles thereto, and stirring the solution.

The organic solvent is not limited, and various organic solvents such as dimethylformamide (DMF), methyl ethyl ketone, and cyclohexanone can be used.

In a case where the sheet-like material 42 is prepared and the coating material is prepared, the coating material is cast (applied) onto the sheet-like material 42, and the organic solvent is evaporated and dried. In this manner, as shown in FIG. 5, the piezoelectric laminate 46 in which the second electrode layer 16 is provided on the second protective layer 20 and the piezoelectric layer 12 is laminated on the second electrode layer 16 is produced.

A casting method of the coating material is not limited, and all known methods (coating devices) such as a bar coater, a slide coater, and a doctor knife can be used.

Alternatively, in a case where the polymer material is a material that can be heated and melted, the piezoelectric laminate 46 as shown in FIG. 5 may be produced by heating and melting the polymer material to produce a melt obtained by adding the piezoelectric particles 26 to the melted material, extruding the melt on the sheet-like material 42 shown in FIG. 4 in a sheet shape by carrying out extrusion molding or the like, and cooling the laminate.

As described above, in the piezoelectric layer 12 a polymer piezoelectric material such as PVDF may be added to the matrix 24, in addition to the polymer material having viscoelasticity at normal temperature.

In a case where the polymer piezoelectric material is added to the matrix 24, the polymer piezoelectric material to be added to the above-described coating material may be dissolved. Alternatively, the polymer piezoelectric material to be added may be added to the heated and melted polymer material having viscoelasticity at normal temperature so that the polymer piezoelectric material is heated and melted.

After forming the piezoelectric layer 12, a calender treatment may be performed as necessary. The calender treatment may be performed once or a plurality of times.

As is well known, the calender treatment is a treatment in which the surface to be treated is pressed while being heated by a heating press, a heating roller, or the like to flatten the surface.

Next, the piezoelectric layer 12 of the piezoelectric laminate 46 including the second electrode layer 16 on the second protective layer 20 and including the piezoelectric layer 12 formed on the second electrode layer 16 is subjected to a polarization treatment (poling). The polarization treatment of the piezoelectric layer 12 may be performed before the calender treatment, but it is preferable that the polarization treatment is performed after the calender treatment.

A method of performing the polarization treatment on the piezoelectric layer 12 is not limited, and a known method can be used. For example, electric field poling in which a DC electric field is directly applied to a target to be subjected to the polarization treatment is exemplified. In a case of performing the electric field poling, the electric field poling treatment may be performed using the first electrode layer 14 and the second electrode layer 16 by forming the first electrode layer 14 before the polarization treatment.

In addition, in the piezoelectric film 10 according to the embodiment of the present invention, it is preferable that the polarization treatment is performed in the thickness direction instead of the plane direction of the piezoelectric layer 12.

Next, as shown in FIG. 6, the sheet-like material 40 which has been prepared in advance is laminated on the piezoelectric layer 12 side of the piezoelectric laminate 46 which has been subjected to the polarization treatment, such that the first electrode layer 14 faces the piezoelectric layer 12.

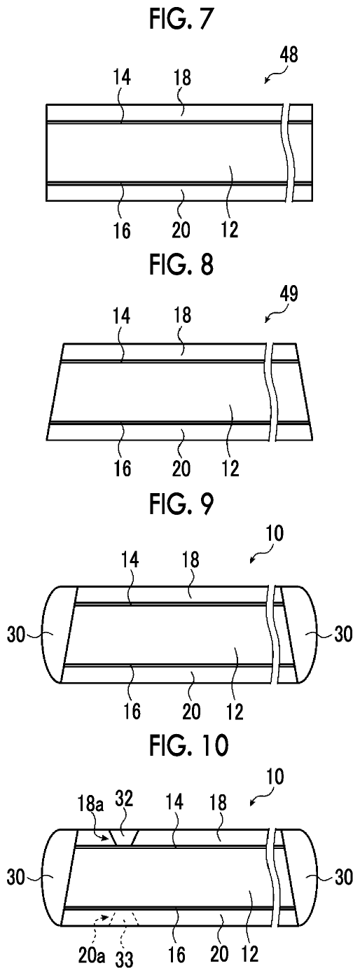

Furthermore, a large-sized (long) laminated film 48 as shown in FIG. 7 is produced by subjecting the laminate to a thermal compression bonding using a heating press device, a heating roller, or the like such that the first protective layer 18 and the second protective layer 20 are sandwiched, and bonding the piezoelectric laminate 46 on the sheet-like material 40.

Alternatively, the laminated film 48 may be produced by bonding and preferably further compression-bonding the piezoelectric laminate 46 and the sheet-like material 40 to each other using an adhesive.

The laminated film 48 may be produced using the cut sheet-like material 42 and the cut sheet-like material 40, or may be produced by roll-to-roll.

Next, as conceptually shown in FIG. 8, the produced large-sized laminated film 48 is cut into a predetermined shape, for example, a rectangular shape using a cutting unit such as a cutter blade and a punching mold, thereby forming a cut sheet-like laminated film 49.

Here, in the present invention, as shown in FIG. 8, the laminated film 48 is cut such that the edge surface thereof is oblique to the main surface. An angle at this time may be adjusted such that the ratio p of the inter-electrode distance di on the edge surface of the laminated film 49 (piezoelectric film 10) to the thickness t of the piezoelectric layer 12 is 103% or more and less than 120%.

Next, as shown in FIG. 9, the edge surface sealing layer 30 is formed on the edge surface of the laminated film 49.

The method of forming the edge surface sealing layer 30 on the edge surface of the laminated film 49 is not limited, and a known forming method (film forming method) according to the forming material of the edge surface sealing layer 30 can be used.

Examples thereof include a method of bonding an insulating pressure-sensitive adhesive tape, a method of applying a liquid obtained by dissolving a material to be the edge surface sealing layer 30 and drying the liquid, a method of applying a liquid obtained by melting a material to be the edge surface sealing layer 30 and curing the liquid, and a method of dissolving a resin to be the edge surface sealing layer 30 in a solvent and spraying and drying the solution. As described above, in a case where the thermoplastic resin or the UV curable resin is used as the material of the edge surface sealing layer 30, a liquid obtained by melting a material to be the edge surface sealing layer 30 may be applied, and then cooled or irradiated with UV to cure the liquid and form the edge surface sealing layer 30.

The method of applying the liquid at this time is not limited, and various known methods can be used. Examples thereof include spray coating and dip coating.

In addition, as described above, the edge surface sealing layer 30 may be formed up to the main surface of the first protective layer 18 and/or the main surface of the second protective layer 20 as necessary.

The piezoelectric film according to the embodiment of the present invention can be produced by the above-described steps.

The piezoelectric film 10 to be produced in the above-described manner is polarized in the thickness direction instead of the plane direction, and thus excellent piezoelectric characteristics are obtained even in a case where a stretching treatment is not performed after the polarization treatment. Therefore, the piezoelectric film 10 has no in-plane anisotropy as a piezoelectric characteristic, and stretches and contracts isotropically in all directions in the plane direction in a case where a driving voltage is applied.

Subsequently, a process of leading out an electrode may be performed. That is, as shown in FIG. 10, the through-hole 18a is formed in the first protective layer 18, and the first connecting member 32 is formed in the through-hole 18a to connect the first lead-out electrode 34. Furthermore, the through-hole 20a is formed in the second protective layer 20, and the second connecting member 33 is formed in the through-hole 20a to connect the second lead-out electrode 36.

Methods of forming the through-hole 18a and the through-hole 20a, the first connecting member 32 and the second connecting member 33, and the first lead-out electrode 34 and the second lead-out electrode 36 are as described above.

### Piezoelectric Speaker

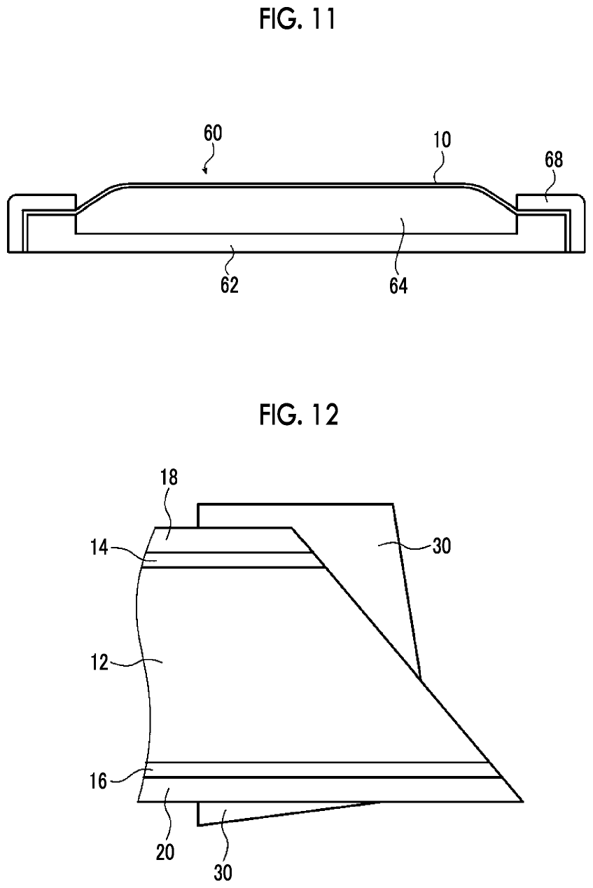

FIG. 11 conceptually shows an example of a flat plate type piezoelectric speaker including the piezoelectric film 10 according to the embodiment of the present invention.

A piezoelectric speaker 60 is a flat plate type piezoelectric speaker which uses the piezoelectric film 10 as a vibration plate converting an electrical signal into vibration energy. The piezoelectric speaker 60 can also be used as a microphone, a sensor, or the like.

The piezoelectric speaker 60 is configured to include the piezoelectric film 10, a case 62, a viscoelastic support 64, and a frame 68.

The case 62 is a thin housing which is formed of plastic or the like and has one opening surface. Examples of a shape of the housing include a rectangular parallelepiped shape, a cubic shape, and a cylindrical shape.

In addition, the frame 68 is a frame material which has, in the center thereof, a through-hole having the same shape as the opening surface of the case 62 and engages with the opening surface side of the case 62.

The viscoelastic support 64 is a support used for efficiently converting the stretching and contracting movement of the piezoelectric film 10 into a forward and rearward movement (a movement in the direction perpendicular to the surface of the film) by having moderate viscosity and elasticity, supporting the piezoelectric film 10, and applying a constant mechanical bias to any place of the piezoelectric film. Examples thereof include wool felt, nonwoven fabric such as wool felt containing PET, and glass wool.

The piezoelectric speaker 60 is configured by accommodating the viscoelastic support 64 in the case 62, covering the case 62 and the viscoelastic support 64 with the piezoelectric film 10, and fixing the frame 68 to the case 62 in a state of pressing a periphery of the piezoelectric film 10 against an upper end surface of the case 62 by the frame 68.

Here, in the piezoelectric speaker 60, the viscoelastic support 64 has a shape in which a height (thickness) thereof is larger than a height of an inner surface of the case 62.

Therefore, in the piezoelectric speaker 60, the viscoelastic support 64 is held in a state of being thinned by being pressed downward by the piezoelectric film 10 at the peripheral portion of the viscoelastic support 64. In addition, in the peripheral portion of the viscoelastic support 64, a curvature of the piezoelectric film 10 suddenly fluctuates, and a rising portion which decreases in height toward the periphery of the viscoelastic support 64 is formed in the piezoelectric film 10. Furthermore, a central region of the piezoelectric film 10 is pressed by the viscoelastic support 64 having a square columnar shape, and has a (approximately) planar shape.

In the piezoelectric speaker 60, in a case where the piezoelectric film 10 stretches in the plane direction due to the application of the driving voltage to the first electrode layer 14 and the second electrode layer 16, the rising portion of the piezoelectric film 10 changes an angle in a rising direction due to the action of the viscoelastic support 64 in order to absorb the stretched part. As a result, the piezoelectric film 10 having the planar portion moves upward.

On the contrary, in a case where the piezoelectric film 10 contracts in the plane direction due to the application of the driving voltage to the first electrode layer 14 and the second electrode layer 16, the rising portion of the piezoelectric film 10 changes an angle in a falling direction (a direction approaching the flat surface) in order to absorb the contracted part. As a result, the piezoelectric film 10 having the planar portion moves downward.

The piezoelectric speaker 60 generates a sound by the vibration of the piezoelectric film 10.

In the piezoelectric film 10, the conversion from the stretching and contracting movement to the vibration can also be achieved by holding the piezoelectric film 10 in a bent state.

Therefore, the piezoelectric film 10 can function as a piezoelectric speaker having flexibility by being simply maintained in a bent state instead of the piezoelectric speaker 60 having rigidity in a flat plate shape, as shown in FIG. 11.

Such a piezoelectric speaker including the piezoelectric film 10 can be accommodated in a bag or the like by, for example, being rolled or folded using the favorable flexibility. Therefore, with the piezoelectric film 10, a piezoelectric speaker which can be easily carried even in a case where the piezoelectric speaker has a certain size can be realized.

In addition, as described above, the piezoelectric film 10 has excellent elasticity and excellent flexibility, and has no in-plane anisotropy as a piezoelectric characteristic. Therefore, in the piezoelectric film 10, a change in acoustic quality is small regardless of the direction in which the film is bent, and a change in acoustic quality with respect to the change in curvature is also small. Accordingly, the piezoelectric speaker including the piezoelectric film 10 has a high degree of freedom of the installation place, and can be attached to various articles as described above. For example, a so-called wearable speaker can be realized by attaching the piezoelectric film 10 to clothes such as a suit and portable items such as a bag in a bent state.

Furthermore, as described above, the piezoelectric film according to the embodiment of the present invention can be used for a speaker of a display device by bonding the piezoelectric film to a display device having flexibility, such as an organic EL display device having flexibility and a liquid crystal display device having flexibility.

As described above, since the piezoelectric film 10 stretches and contracts in the plane direction in a case where a voltage is applied, and vibrates suitably in the thickness direction due to the stretch and contraction in the plane direction, a favorable acoustic characteristic of outputting a sound with a high sound pressure is exhibited, for example, in a case where the piezoelectric film is used for a piezoelectric speaker or the like.

The piezoelectric film 10, which exhibits favorable acoustic characteristics, that is, high stretch and contraction performance due to piezoelectricity satisfactorily acts as a piezoelectric element which vibrates a vibration body such as a vibration plate by laminating a plurality of layers of the piezoelectric films.

In a case of lamination of the piezoelectric films 10, each piezoelectric film may not have the first protective layer 18 and/or the second protective layer 20 unless there is a possibility of a short circuit. Alternatively, the piezoelectric films which do not have the first protective layer 18 and/or the second protective layer 20 may be laminated through an insulating layer.

As an example, a speaker in which a laminate of the piezoelectric films 10 is bonded to the vibration plate and the vibration plate is vibrated by the laminate of the piezoelectric films 10 to output a sound may be used. That is, in this case, the laminate of the piezoelectric films 10 acts as a so-called exciter which outputs a sound by vibrating the vibration plate.

By applying a driving voltage to the laminated piezoelectric films 10, each piezoelectric film 10 stretches and contracts in the plane direction, and the entire laminate of the piezoelectric films 10 stretches and contracts in the plane direction due to the stretch and contraction of each piezoelectric film 10. The vibration plate to which the laminate has been bonded is bent due to the stretch and contraction of the laminate of the piezoelectric films 10 in the plane direction, and as a result, the vibration plate vibrates in the thickness direction. The vibration plate generates a sound using the vibration in the thickness direction. The vibration plate vibrates according to the magnitude of the driving voltage applied to the piezoelectric film 10 and generates the sound according to the driving voltage applied to the piezoelectric film 10.

Therefore, the piezoelectric film 10 itself does not output a sound in this case.

Therefore, even in a case where the rigidity of each piezoelectric film 10 is low and the stretching and contracting force thereof is small, the rigidity is increased by laminating the piezoelectric films 10, and the stretching and contracting force as the entire laminate is increased. As a result, in the laminate of the piezoelectric films 10, even in a case where the vibration plate has a certain degree of rigidity, the vibration plate is sufficiently bent with a large force, and the vibration plate can be sufficiently vibrated in the thickness direction, so that the vibration plate can generate the sound.

In the laminate (piezoelectric element) of the piezoelectric films 10, the number of laminated piezoelectric films 10 is not limited, and the number of sheets providing a sufficient amount of vibration may be appropriately set according to, for example, the rigidity of the vibration plate to be vibrated.

One piezoelectric film 10 can also be used as a similar exciter (piezoelectric element) in a case where one piezoelectric film has a sufficient stretching and contracting force.

The vibration plate vibrated by the laminate of the piezoelectric film 10 is not limited, and various sheet-like materials (such as plate-like materials and films) can be used.

Examples thereof include a resin film consisting of polyethylene terephthalate (PET) and the like, foamed plastic consisting of foamed polystyrene and the like, a paper material such as a corrugated cardboard material, a glass plate, and wood. Furthermore, a device such as a display device may be used as the vibration plate in a case where the device can be sufficiently bent.

It is preferable that the laminate of the piezoelectric films 10 is obtained by bonding adjacent piezoelectric films with a bonding layer (bonding agent). In addition, it is preferable that the laminate of the piezoelectric films 10 and the vibration plate are also bonded to each other with a bonding layer.

The bonding layer is not limited, and various layers which can bond materials to be bonded can be used. Therefore, the bonding layer may consist of a pressure sensitive adhesive or an adhesive. From the viewpoint that a solid and hard bonding layer is obtained after the bonding, it is preferable to use an adhesive layer consisting of an adhesive.

Regarding the above points, the same applies to a laminate formed by folding a long piezoelectric film 10, which will be described later.

In the laminate of the piezoelectric films 10, the polarization direction of each piezoelectric film 10 to be laminated is not limited. As described above, the polarization direction of the piezoelectric film 10 is the polarization direction in the thickness direction.

Therefore, in the laminate of the piezoelectric films 10, the polarization directions may be the same for all the piezoelectric films 10, and piezoelectric films having different polarization directions may be present.

Here, in the laminate of the piezoelectric films 10, it is preferable that the piezoelectric films 10 are laminated such that the polarization directions of adjacent piezoelectric films 10 are opposite to each other.

In the piezoelectric film 10, the polarity of the voltage to be applied to the piezoelectric layer 12 depends on the polarization direction of the piezoelectric layer 12. Therefore, even in a case where the polarization direction is directed from the first electrode layer 14 toward the second electrode layer 16 or from the second electrode layer 16 toward the first electrode layer 14, the polarity of the first electrode layer 14 and the polarity of the second electrode layer 16 in all the piezoelectric films 10 to be laminated are set to be the same as each other.

Therefore, even in a case where the electrode layers of the adjacent piezoelectric films 10 come into contact with each other, since the electrode layers in contact with each other have the same polarity by reversing the polarization directions of the adjacent piezoelectric films 10, there is no risk of a short circuit.

The laminate (piezoelectric element) of the piezoelectric films 10 may be configured such that a long piezoelectric film 10 is folded, for example, once or more times, preferably a plurality of times, to laminate a plurality of layers of the piezoelectric film 10.

The piezoelectric element in which the long piezoelectric film 10 is folded and laminated has the following advantages.

That is, in the piezoelectric element in which a plurality of cut sheet-like piezoelectric films 10 are laminated, it is necessary to connect the first electrode layer 14 and the second electrode layer 16 to a driving power supply for each piezoelectric film. On the contrary, in the configuration in which the long piezoelectric film 10 is folded and laminated, only one sheet of the long piezoelectric film 10 can form the laminate. In addition, in the configuration in which the long piezoelectric film 10 is folded and laminated, only one power supply is required for applying the driving voltage, and the electrodes may be led out from the piezoelectric film 10 at one place.

Furthermore, in the configuration in which the long piezoelectric film 10 is folded and laminated, polarization directions of adjacent piezoelectric films 10 are inevitably opposite to each other.

Hereinbefore, the piezoelectric film according to the embodiment of the present invention has been described in detail, but the present invention is not limited to the above-described examples and various improvements and changes can be made without departing from the spirit of the present invention.

### EXAMPLES

Hereinafter, the present invention will be described in more detail with reference to specific examples of the present invention. The present invention is not limited to the examples, and the materials, the used amounts, the proportions, the treatment contents, the treatment procedures, and the like shown in the following examples can be appropriately changed within a range not departing from the scope of the present invention.

### Production of Laminated Film

A large-sized laminated film was produced by the method shown in FIGS. 4 to 7.

First, cyanoethylated PVA (CR-V manufactured by Shin-Etsu Chemical Co., Ltd.) was dissolved in dimethylformamide (DMF) at the following compositional ratio. Thereafter, PZT particles as piezoelectric particles were added to the solution at the following compositional ratio, and the solution was stirred using a propeller mixer (rotation speed: 2000 rpm), thereby preparing a coating material for forming a piezoelectric layer.
PZT Particles: 300 parts by mass
Cyanoethylated PVA: 30 parts by mass
DMF: 70 parts by mass

PZT particles which were obtained by sintering mixed powder, formed by wet-mixing powder of a Pb oxide, a Zr oxide, and a Ti oxide as main components using a ball mill such that the amount of Zr and the amount of Ti respectively reached 0.52 moles and 0.48 moles with respect to 1 mole of Pb, at 800° C. for 5 hours and being subjected to a crushing treatment were used as the PZT particles.

On the other hand, a sheet-like material obtained by performing vacuum vapor deposition on a copper thin film having a thickness of 0.1 μm was prepared on a PET film having a thickness of 4 μm. That is, in the present example, the first electrode layer and the second electrode layer were copper-deposited thin films having a thickness of 0.1 μm, and the first protective layer and the second protective layer were PET films having a thickness of 4 μm.

The second electrode layer (copper-deposited thin film) of the sheet-like material was coated with the coating material for forming a piezoelectric layer, which was prepared in advance, using a slide coater. The coating material was applied so that a film thickness of the coating film after drying was 50 μm.

Next, the material obtained by coating the sheet-like material with the coating material was heated and dried on a hot plate at 120° C. to evaporate DMF. In this manner, a piezoelectric laminate in which the second electrode layer made of copper was provided on the second protective layer made of PET and the piezoelectric layer (polymer-based piezoelectric composite material layer) having a thickness of 50 μm was formed thereon was produced.

The produced piezoelectric layer was subjected to a polarization treatment in the thickness direction.

A sheet-like material obtained by vapor-depositing an identical thin film on the PET film was laminated on the laminate which had been subjected to the polarization treatment such that the first electrode layer (copper thin film side) faced the piezoelectric layer.

Next, a large-sized laminated film as shown in FIG. 7 was produced by performing thermal compression bonding on the laminate of the laminate and the sheet-like material at a temperature of 120° C. using a laminator device, and bonding and adhering the piezoelectric composite material and the first electrode layer to each other.

### Examples 1 to 4 and Comparative Examples 1 to 3

The produced laminated film was cut into a size of 210×300 mm by changing the cutter blade to be used and the cutting angle in various ways to produce a cut sheet-like laminated film.

With each of the produced laminated films, the inter-electrode distance di between the first electrode layer and the second electrode layer on the edge surface and the thickness t of the piezoelectric layer in the end part were measured by the above-described methods using SEM-EDS, and the ratio p [%] of the thickness t to the inter-electrode distance d₁ was calculated. In the measurement using SEM-EDS, SU8220 manufactured by Hitachi High-Tech Corporation was used as the SEM and XFash 5060FQ manufactured by Bruker Corporation was used as the EDS.

Next, the edge surface sealing layer was formed on the end part of the cut laminated film to cover the entire edge surface, thereby producing a piezoelectric film.

In Examples 1, 2, and 4 and Comparative Examples 1 and 2, a thermoplastic resin (EVA) was used as a material of the edge surface sealing layer, and the solution applied to the end part was cooled and cured. In addition, in Example 3, a UV curable resin (urethane acrylate) was used as the material of the edge surface sealing layer, and the solution applied to the end part was cooled and cured. In addition, in Comparative Example 3, the edge surface was not sealed.

In addition, the thickness d₂ of the edge surface sealing layer formed on the main surface of the protective layer was set to 50 μm in Examples 1 to 3 and Comparative Examples 1 and 2, and was set to 100 μm in Example 4.

### Evaluation

### Availability of Sealing

Whether or not the edge surface of the laminated film was sealed by the edge surface sealing layer was observed with an optical microscope. Four sides of the edge surface of the laminated film were observed with the optical microscope in a direction perpendicular to the edge surface, and a length at which a part of the edge surface was exposed from the sealing layer was measured. A case where the total length of the edge surface which was not covered with the sealing layer and was exposed was 5% or less of the total length of the four sides of the edge surface of the laminated film was determined to be able to be sealed, and a case of being more than 5% was determined to be not able to be sealed.

### Presence or Absence of Dielectric Breakdown

A wiring line was connected to the electrode layer of the produced piezoelectric film. The piezoelectric film was placed in an anechoic chamber, a voltage at which an electric field between the electrode layers of the piezoelectric film was at 3 V/μm was applied as an input signal through a power amplifier, and a sound was recorded with a microphone placed vertically at a distance of 50 cm from the center of the piezoelectric film.

From the recorded data, the presence or absence of dielectric breakdown was evaluated as follows.
A: sound was produced without any problem.
B: sound was produced after a discharge sound.

### Sound Pressure

The produced piezoelectric film was laminated in five layers, and a wiring line was connected to the electrode layer to produce a piezoelectric element. In this case, the laminated size of the piezoelectric element was set to 50×200 mm, and the number of laminated layers was 5. The produced piezoelectric element was attached to a vibration plate as an exciter, and a sound pressure was measured. As the vibration plate, an aluminum plate (A5052P) having a thickness of 0.8 mm, a length of 450 mm, and a width of 500 mm was used. A lateral direction of the vibration plate and a longitudinal direction of the piezoelectric element were aligned, and the piezoelectric element was bonded to the center of the laminated portion, aligned with the center of the vibration plate. A sine sweep signal of a frequency of 5 to 10 kHz and an applied voltage of 50 Vrms was input to the piezoelectric element, the sound pressure was measured with a microphone placed at a distance of 1 m from the center of the vibration plate, and the average of the sound pressure of each frequency was defined as representative sound pressure.
A: 85 dB or more
B: 80 dB or more and less than 85 dB
C: less than 80 dB

The results are shown in Table 1.

TABLE 1

| | Piezoelectric film | | | | | | | | | Evaluation | | |
|---|---|---|---|---|---|---|---|---|---|---|---|---|
| | Thickness t | Inter- | | | Edge surface sealing layer | | | | | Avail- | | |
| | of | electrode | | | | Thick- | Thick- | | | ability | | Sound |
| | piezoelectric | distance d₁ | Ratio | Type of | | ness | ness | Width | Width | of | Dielectric | pres- |
| | layer μm | μm | p | blade used | Material | d₂ μm | d₃ μm | d₄ | d₅ | sealing | breakdown | sure |
| Example 1 | 50 | 52 | 104% | Shear | Thermoplastic | 50 | 30 | 500 | 510 | A | A | A |
| | | | | blade | resin | | | | | | | |
| Example 2 | 50 | 58 | 116% | Shear | Thermoplastic | 50 | 30 | 500 | 510 | A | A | A |
| | | | | blade | resin | | | | | | | |
| Example 3 | 50 | 52 | 104% | Shear | UV curable | 50 | 30 | 500 | 510 | A | A | A |
| | | | | blade | resin | | | | | | | |
| Example 4 | 50 | 52 | 104% | Shear | Thermoplastic | 100 | 30 | 500 | 510 | A | A | B |
| | | | | blade | resin | | | | | | | |
| Comparative | 50 | 60 | 120% | Cutter | Thermoplastic | 50 | 30 | 500 | 510 | B | B | A |
| Example 1 | | | | knife | resin | | | | | | | |
| Comparative | 50 | 51 | 102% | Thompson | Thermoplastic | 50 | 30 | 500 | 510 | A | B | A |
| Example 2 | | | | blade | resin | | | | | | | |
| Comparative | 50 | 52 | 104% | Shear | None | — | — | — | — | — | B | A |
| Example 3 | | | | blade | | | | | | | | |

From Table 1, it was found that, in Examples of the present invention, the dielectric breakdown could be suppressed as compared with Comparative Examples. On the contrary, in Comparative Examples, the dielectric breakdown occurred between the electrode layers at the edge surface during application of a high voltage, and no sound was produced. In addition, from Comparative Example 1, it was found that, in a case where the ratio p was too large, the edge surface could not be appropriately sealed, and the dielectric breakdown easily occurred.

In addition, from the comparison between Example 1 and Example 4, it was found that the thickness d₂ of the edge surface sealing layer was preferably 50 μm or less.

From the above results, the effect of the present invention is clear.

The piezoelectric film according to the embodiment of the present invention is suitably used as the following, for example: as various sensors such as a sound wave sensor, an ultrasonic wave sensor, a pressure sensor, a tactile sensor, a strain sensor, and a vibration sensor (which are useful particularly for an infrastructure examination such as crack detection and a manufacturing site inspection such as foreign matter contamination detection); acoustic devices such as microphones, pickups, speakers, and exciters (as specific applications, noise cancellers (used for cars, trains, airplanes, robots, and the like), artificial voice bands, buzzers to prevent pests and beasts from invading, furniture, wallpaper, photo, helmet, goggles, headrest, signage, robot, and the like are exemplified); haptics used for application to automobiles, smartphones, smart watches, games, and the like; ultrasonic transducers such as ultrasound probe and hydrophones; actuators used for prevention of attachment of water droplets, transportation, agitation, dispersion, polishing, and the like; damping materials (dampers) used for containers, vehicles, buildings, sports equipment such as skis and rackets; and vibration power generator used for application to roads, floors, mattresses, chairs, shoes, tires, wheels, computer keyboards, and the like.

### EXPLANATION OF REFERENCES

10: piezoelectric film
12: piezoelectric layer
14: first electrode layer
16: second electrode layer
18: first protective layer
18a, 20a: through-hole
20: second protective layer
24: polymer matrix
26: piezoelectric particle
30: edge surface sealing layer
32: first connecting member
33: second connecting member
34: first lead-out electrode
36: second lead-out electrode
40, 42: sheet-like material
46: piezoelectric laminate
48: laminated film
60: piezoelectric speaker
62: case
64: viscoelastic support
68: frame
d₁: inter-electrode distance
d₂: thickness of edge surface sealing layer on main surface
d₃: thickness of edge surface sealing layer in plane direction
d₄, d₅: width of edge surface sealing layer on main surface
t: thickness of piezoelectric layer

What is claimed is:

1. A piezoelectric film comprising:
a piezoelectric layer which contains piezoelectric particles in a matrix containing a polymer material;
electrode layers which are provided on both surfaces of the piezoelectric layer; and
protective layers which are provided on the electrode layers,
wherein the piezoelectric film further includes an edge surface sealing layer consisting of a material containing a resin, the edge surface sealing layer covering an edge surface of the piezoelectric film, and
an inter-electrode distance on the edge surface of the piezoelectric film is 30 μm or more, and is 103% or more and less than 120% with respect to a thickness of the piezoelectric layer.

2. The piezoelectric film according to claim 1,
wherein the material of the edge surface sealing layer contains a thermoplastic resin.

3. The piezoelectric film according to claim 1,
wherein the material of the edge surface sealing layer contains an ultraviolet curable resin.

4. The piezoelectric film according to claim 1,
wherein a thickness of the edge surface sealing layer formed on a main surface of the protective layer is 50 μm or less.

5. The piezoelectric film according to claim 1,
wherein a width of the edge surface sealing layer in a plane direction on a main surface of the piezoelectric film is 100 μm or more and 5,000 μm or less.

6. The piezoelectric film according to claim 1,
wherein a thickness of the edge surface sealing layer in a plane direction from the edge surface of the piezoelectric film is 50 μm or less.

7. A piezoelectric element obtained by laminating a plurality of layers of the piezoelectric films according to claim 1.

8. A piezoelectric element obtained by laminating a plurality of layers of the piezoelectric film according to claim 1 by folding the piezoelectric film one or more times.

9. The piezoelectric film according to claim 2,
wherein the material of the edge surface sealing layer contains an ultraviolet curable resin.

10. The piezoelectric film according to claim 2,
wherein a thickness of the edge surface sealing layer formed on a main surface of the protective layer is 50 μm or less.

11. The piezoelectric film according to claim 2,
wherein a width of the edge surface sealing layer in a plane direction on a main surface of the piezoelectric film is 100 μm or more and 5,000 μm or less.

12. The piezoelectric film according to claim 2,
wherein a thickness of the edge surface sealing layer in a plane direction from the edge surface of the piezoelectric film is 50 μm or less.

13. A piezoelectric element obtained by laminating a plurality of layers of the piezoelectric films according to claim 2.

14. A piezoelectric element obtained by laminating a plurality of layers of the piezoelectric film according to claim 2 by folding the piezoelectric film one or more times.

15. The piezoelectric film according to claim 3,
wherein a thickness of the edge surface sealing layer formed on a main surface of the protective layer is 50 μm or less.

16. The piezoelectric film according to claim 3,
wherein a width of the edge surface sealing layer in a plane direction on a main surface of the piezoelectric film is 100 μm or more and 5,000 μm or less.

17. The piezoelectric film according to claim 3,
wherein a thickness of the edge surface sealing layer in a plane direction from the edge surface of the piezoelectric film is 50 μm or less.

18. A piezoelectric element obtained by laminating a plurality of layers of the piezoelectric films according to claim 3.

19. A piezoelectric element obtained by laminating a plurality of layers of the piezoelectric film according to claim 3 by folding the piezoelectric film one or more times.

20. The piezoelectric film according to claim 4,
wherein a width of the edge surface sealing layer in a plane direction on a main surface of the piezoelectric film is 100 μm or more and 5,000 μm or less.
